(19) United States
(12) Patent Application Publication
(10) Pub. No.: US 2011/0109324 A1
(43) Pub. Date: May 12, 2011

(54) Microwave system for detecting bubbles

(76) Inventor: Jose Julio Moya Garcia, Madrid (ES)

(21) Appl. No.: 10/510,180

(22) PCT Filed: Jul. 24, 2003
(86) PCT No.: PCT/ES2003/000386

§ 371 Date: Feb. 18, 2005

(30) Foreign Application Priority Data
Jul. 24, 2002 (ES) P200201742

(51) Int. Cl. G01R 27/04

(52) U.S. Cl. 324/639

(57) ABSTRACT

The microwave embolus detector is a device that employs microwaves to detect the presence of air emboli in a flow of paste, which is passed through a Teflon tube or hose, as these microwaves are absorbed to a greater or lesser degree by the paste itself but are not absorbed by air. The level of power received by the receiver is constant provided the flow is homogenous. However, when a bubble appears, diffusion takes place as air does not absorb the microwaves, thus the power received will alter as regards the full scale signal of the homogenous flow. Diffusion may also be caused by the presence of lumps.

### OBJECT OF THE INVENTION

The object of this invention, as expressed in the descriptive paper, is a new system employed to detect bubbles using microwaves, i.e.: the device uses microwaves to detects the presence of air emboli in a flow of paste passing through a tube or hose, as these microwaves are absorbed to a greater or lesser degree by the paste itself but are not absorbed by air, using an emitter and a receiver.

### BACKGROUND OF THE INVENTION

There currently exist other methods for detecting the presence of bubbles in liquids, such as U.S Pat. No. 5,198,776 (30 Mar. 1993), title: The object of this patent is a system that detects the presence of air emboli in a liquid passing through a tube. Said system captures the amplitude of the microwave radiation and detects any drop in this caused by the presence of air bubbles. This patent may represent a potential problem, as it also aims to detect air emboli in a liquid using microwaves. The patent indicates that this is a passive application, which is to say it has only one receiver that picks up the emission of microwaves generated by the liquid itself. This patent focuses on medical aspects and does not specifically refer to very dense liquids (pastes), but rather to blood and other injectable fluids (drugs or liquids used to carry out certain analyses). The patent is referenced to emboli as opposed to any possible lumps or other irregularities in the liquid that are not a result of the presence of bubbles.

The paper describing this invention, the microwave embolus detector, includes a series of new items, for example: said device is not a passive application, but uses an active technique, which is to say, it employs an emitter and a receiver (which may even by the emitter itself), and it is based on the incident radiation diffused by the air emboli. Another new item is the use of pastes, which cannot be considered liquids in the strictest sense, and which do not have the same rheological characteristics as these. Lastly, it also allows the user to detect the level of homogeneity of a paste (whether or not lumps are present).

### A DESCRIPTION OF THE INVENTION

The microwave embolus detector uses microwaves to detect the presence of air emboli in a flow of paste passing through a tube or hose, as these microwaves are absorbed to a greater or lesser degree by the paste itself but are not absorbed by air, using an emitter and a receiver.

The invention operates in the following way: The level of power received by the receiver is constant provided the flow passing through the tube is homogenous. However, when an air bubble is present, diffusion will occur, as air will not absorb these microwaves and the power received will differ from the full scale value of the homogenous flow. Diffusion will also take place, if lumps are found.

The next phase deals with processing the signal provided by the receiver. This signal is filtered, rectified, amplified and then digitalized.

When a bubble appears, the full scale signal will alter and, if this goes beyond a certain limit, an alarm signal will be given. The sensitivity of the device will be higher or lower depending on the level determined for this limit, i.e.: when the limit is lower, the device is more sensitive, however, in this case it will also be affected to a greater degree by noise.

The configuration of the microwave embolus detector is defined by the following elements; a tube made of Teflon, nylon or any other non-metallic material that does not absorb microwaves, a receiver—emitter, an emitter—receiver and a shielded metal case.

It is important to use an inner tube that has been manufactured using a non-metallic material that does not absorb microwaves. The external case should be made of metal so that the microwaves used cannot transfuse, and so that the microwaves from the collateral effects of other devices cannot enter, thus avoiding interference.

### A DETAILED DESCRIPTION OF THE DRAWINGS

For a better understanding of the object of this invention underneath is a description of how it is used in practice and said description is accompanied by drawings.

FIG. 1. This diagram gives a perspective view of the microwave embolus detector and indicates the position of the entry orifice and the opening where the emitter or receiver is located.

FIG. 2. This diagram gives a perspective view with a lengthwise section indicating the position of the Teflon tube and the conduit through which the microwaves circulate.

FIG. 3. This provides a ground view, an elevated view and a perspective view of the Teflon tube.

FIG. 4. This gives a perspective view of the schematic shape of the microwave embolus detector and indicates the position of the orifice through which the material enters and leaves and the location of the emitter and receiver.

FIG. 5. This diagram shows the device and the elements that make up the microwave embolus detector as seen from the front.

FIG. 6. This shows the circuit and indicates the location of the block system of the microwave embolus detector and the flow of the electronic schematics of which it is composed.

FIG. 7. This gives a ground view, an elevated view and a side view of the embolus detector, as well as a perspective view of the equipment with all the elements that form part of the device, such as: the block, the Emitter—Receiver, the impermeable “D” Connector, the Temperature probe, the Resistor and the mechanical pieces that make up the device.

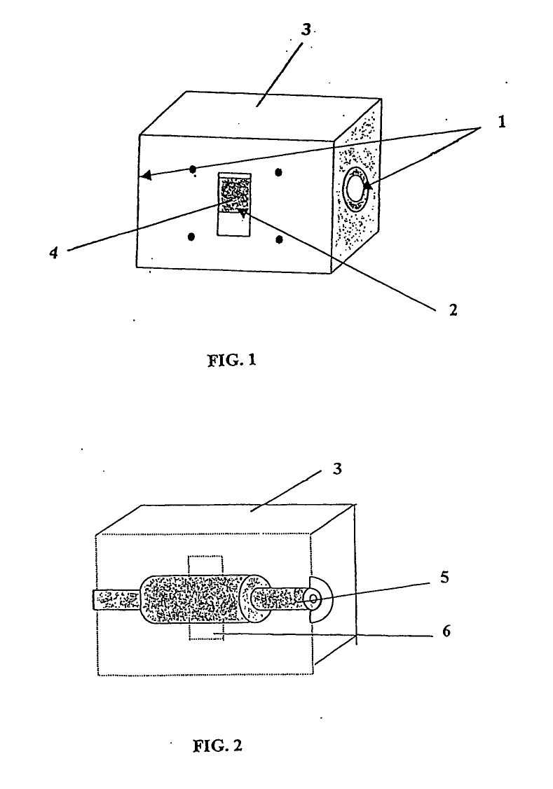

### HOW TO BEST OPERATE THE INVENTION

The microwave embolus detector uses microwaves to detect the presence of air emboli in a flow of paste passing through a tube or hose, as these microwaves are absorbed to a greater or lesser degree by the paste itself but are not absorbed by air, using an emitter or receiver.

The configuration of the embolus detection system, as can be seen in drawings numbers 1 and 5, includes a detection area constructed for this specific purpose, which is known as the shielded metal case or part (3). Inside there is a tube (5) made of Teflon or another similar material. This Teflon tube (5) is located within a metal structure, and both of these parts can be inserted in a circuit for pastes or liquids.

FIG. 2 shows the position of the Teflon tube (5) and the conduit (6), the area or field through which the microwaves circulate.

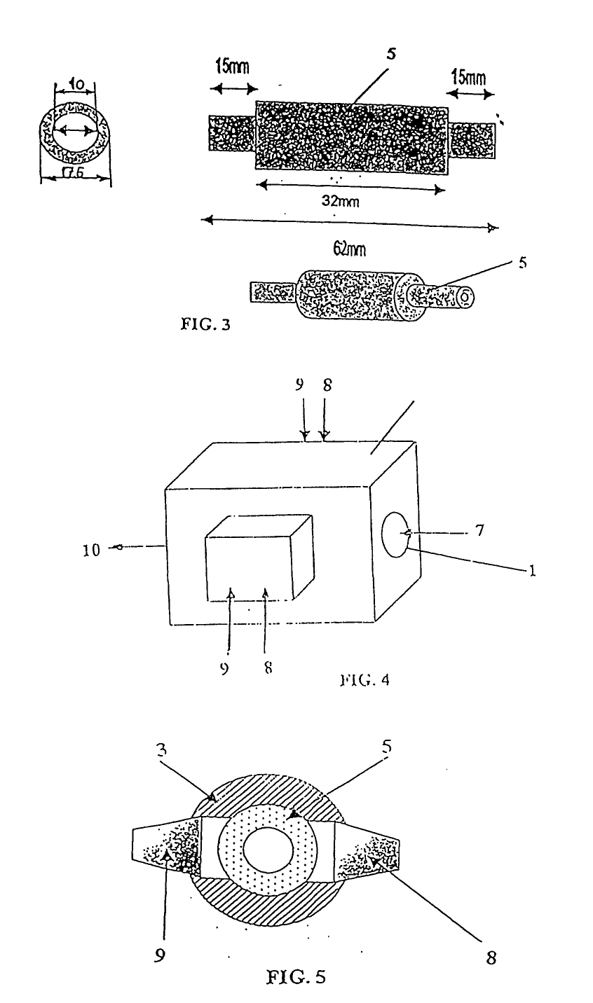

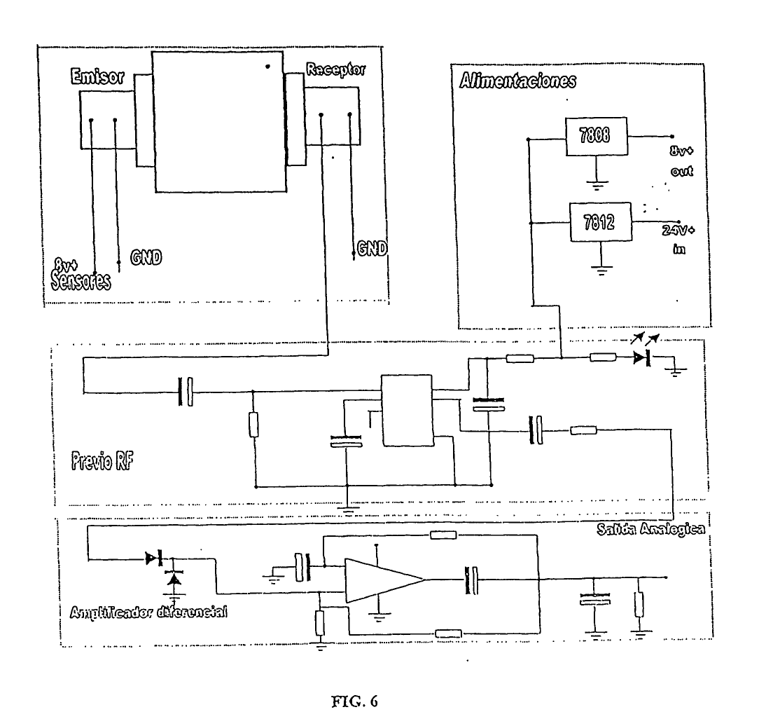

FIG. 3 indicates the dimensions of the Teflon tube (5) located within the structure (3) or the metal body that forms part of the detector.

FIG. 4 shows the detection device, and indicates the position of the emitter (8), receiver (9), as well as where the material enters (7), and leaves (10), once it has passed through the detector.

FIG. 5 is a diagram of the device and the elements of which it is composed. The shielded metal case or structure (3), the tube (5), should be made of Teflon, nylon or another non-metallic material that does not absorb microwaves, the emitter (8), and the receiver (9).

FIG. 5 shows the block groups and the electronic schematic. The microwave emitters are Macom, model MA87728-M01, with a transmission frequency of 10.525 Ghz, X-Band, and a power of 10 mw. The receivers are the same ones used to deal with the signal received. The electronics are divided up into several different blocks, such as: supply, sensors, RF preamplifier, differential amplifier and analogical output.

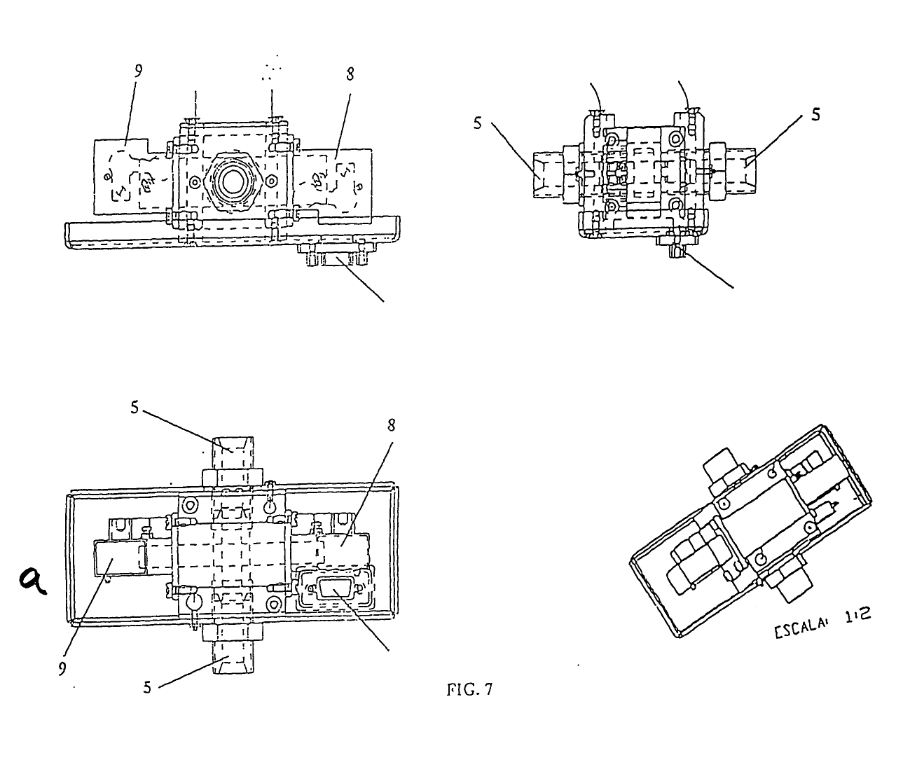

FIG. 7 shows the embolus detecting equipment as a whole, as it can be currently seen, and gives a ground perspective of the embolus detector where the most important parts that make up the device are indicated, such as: the Block, the Tube, the Emitter—Receiver, the impermeable “D” Connector, the Temperature probe, and the Resistor.

The output signal is connected to a PLC, which processes the signal and then sends it to a PC where it can be by dealt with by the signal processing software.

As the nature of this invention has been sufficiently described, as has the way in which it should be used, all that remains is to add that the form, materials and way in which the device as a whole and its individual parts are arranged can be modified, provided said alterations do not significantly vary the characteristics to which the claims laid below refer.

1. Microwave Embolus Detector, whose objective is to detect the presence of air emboli in a flow of paste, characterized in that the flow of paste is passed through a teflon tube or hose using microwaves, since said microwaves are absorbed in a higher or lesser degree by the pastes, using an emitter and a receiver.

2. Microwave Embolus Detector according to claim 1, characterized in that the power received by the receiver is constant provided that the flow of paste is homogeneous, but when an emboli appears said power will diffuse because the air will not absorb, and the power received will be altered compared with the base value of the homogeneous paste, which will also take place if pitch appears.

3. Microwave Embolus Detector, according to the previous claims, characterized in that the treatment of the signal received by the receiver is filtered, rectified, amplified and digitalized.

4. Microwave Embolus Detector, according to the previous claims, characterized in that, when an emboli appears, the base signal is diffused and passes certain threshold, then an outgoing alarm signal is activated, being the sensitiveness of this system related to the level of this limit in the sense that the lesser the lower level, the higher the sensitivity.
